(19) United States
(12) Patent Application Publication
(10) Pub. No.: US 2021/0028192 A1
(43) Pub. Date: Jan. 28, 2021

(54) DISPLAY PANEL AND MANUFACTURING METHOD THEREOF

(71) Applicant: TCL CHINA STAR OPTOELECTRONICS TECHNOLOGY CO., LTD., Shenzhen (CN)

(72) Inventor: Yibiao YIN, Shenzhen (CN)

(73) Assignee: TCL CHINA STAR OPTOELECTRONICS TECHNOLOGY CO., LTD., Shenzhen (CN)

(21) Appl. No.: 16/615,297

(22) PCT Filed: Sep. 17, 2019
(86) PCT No.: PCT/CN2019/106280

§ 371 Date: Nov. 20, 2019

(30) Foreign Application Priority Data
Jul. 24, 2019 (CN) 201910672175.X

(51) Int. Cl. H01L 27/12

(52) U.S. Cl. CPC H01L 27/124; H01L 27/1259

(57) ABSTRACT

A display panel and manufacturing method thereof, and the method of manufacturing the display panel is used for improving metal light leakage, including etching a substrate by an etching process; after etching the substrate by performing the etching process, disposing a modified layer on a side edge of a metal line of the substrate; and after disposing the modified layer on the side edge of the metal line of the substrate, removing a photoresist layer on the substrate. By disposing the modified layer to absorb reflection of diffracted light, light leakage at the side edge of the metal line is reduced, and display contrast is improved.

### FIELD OF INVENTION

The present disclosure relates to the field of display technologies, and more particularly, to a display panel and a method of manufacturing thereof.

### BACKGROUND OF INVENTION

Please refer to FIG. 1 and FIG. 2, which are respectively a top schematic view of a prior art display panel and a cross-sectional view of R1 position in FIG. 1. As shown in the figures, incident light IR1 is irradiated upward from bottom of a substrate S, wherein the incident light is linearly polarized light. Furthermore, intersection angle of metal lines ML on the panel is not a right angle, so a diffraction SC1 is generated at an edge of the metal lines ML, and the diffraction SC1 is then reflected by metal taper at the edge of the metal lines ML, thereby generating a reflected light RF1, resulting in the problem of light leakage, which is common in current display panels.

Therefore, there is need to provide a display panel and a method of manufacturing the display panel to solve the problems of the prior art.

### SUMMARY OF INVENTION

To solve the above problems, the present disclosure provides a display panel and a method of manufacturing the display panel which can reduce light leakage of metal lines side edges and enhance the contrast of display panel.

To achieve the above object, the present disclosure provide a method of manufacturing a display panel, wherein method of manufacturing the display panel use for improving light leakage of metal, including etching a substrate by performing an etching process; after etching the substrate by performing the etching process, disposing a modified layer on side edge of a metal line of the substrate; and after disposing the modified layer on side edge of the metal line of the substrate, removing a photoresist layer on the substrate.

In an embodiment of the present disclosure, the modified layer is disposed on the metal line by performing an oxidation process.

In an embodiment of the present disclosure, the modified layer is disposed on the metal line by performing a heat treatment process.

In an embodiment of the present disclosure, the modified layer is disposed on the metal line by performing an ion implantation process.

In an embodiment of the present disclosure, material of the metal line includes copper.

In an embodiment of the present disclosure, the modified layer is formed by applying an oxidative plasma treatment process to the metal line.

In an embodiment of the present disclosure, material of the modified layer includes copper oxide.

In an embodiment of the present disclosure, the modified layer covers side edge of the metal line.

To achieve the above object, the present disclosure further provides a display panel for improving the light leakage of metal, including a substrate; a metal line, disposing on the substrate; wherein the side edge of the metal line is provided with a modified layer.

In an embodiment of the present disclosure, an oxygen content of the modified layer is more than an oxygen content of side edge of the metal line.

In an embodiment of the present disclosure, a carbon content of the modified layer is more than a carbon content of side edge of the metal line.

In an embodiment of the present disclosure, an ion content of the modified layer is more than an ion content of side edge of the metal line.

In an embodiment of the present disclosure, material of the metal line includes copper.

In an embodiment of the present disclosure, material of the modified layer comprises copper oxide.

In an embodiment of the present disclosure, the modified layer covers side edge of the metal line.

To achieve the above object, the present disclosure further provides a display panel, including a substrate; a metal line, disposing on the substrate; wherein side edge of the metal line is provided with a modified layer, the modified layer covers side edge of the metal line, an oxygen content of the modified layer is more than an oxygen content of side edge of the metal line.

In an embodiment of the present disclosure, a carbon content of the modified layer is more than a carbon content of side edge of the metal line.

In an embodiment of the present disclosure, an ion content of the modified layer is more than an ion content of side edge of the metal line.

In an embodiment of the present disclosure, material of the metal line includes copper.

In an embodiment of the present disclosure, material of the modified layer comprises copper oxide.

In order to make the above description of the present disclosure more comprehensible, the preferred embodiments are described below, and in conjunction with the drawings, the detailed description is as follows:

### DESCRIPTION OF DRAWINGS

FIG. 1 shows a top schematic view of a prior art display panel.

FIG. 2 shows a cross-sectional schematic view of R1 position in FIG. 1.

FIG. 3 shows a flowchart of a method of manufacturing a display panel according an embodiment of the present disclosure.

FIG. 4 shows a schematic block diagram according to a first state of a display panel according an embodiment of the present disclosure.

FIG. 5 shows a schematic block diagram according to a second state of the display panel according an embodiment of the present disclosure.

FIG. 6 shows a schematic block diagram according to a third state of the display panel according an embodiment of the present disclosure.

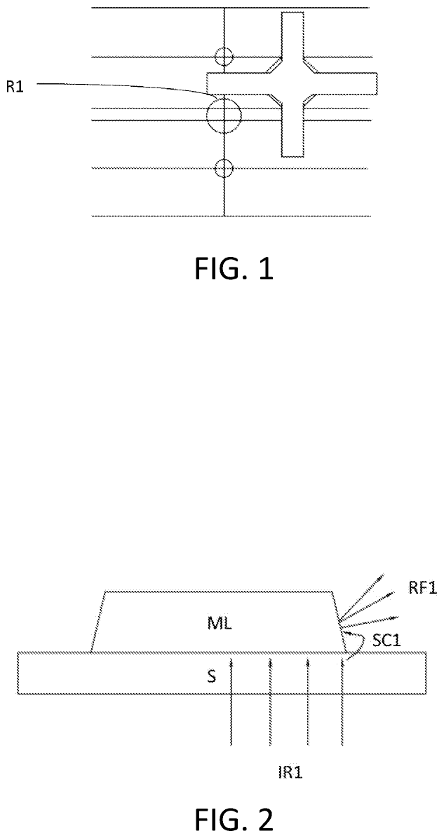

### DETAILED DESCRIPTION OF PREFERRED EMBODIMENTS

In order to make the above description of the present disclosure and other objects, features, and advantages of the present disclosure more comprehensible, preferred embodiments are described below, and are described in detail below with reference to the accompanying drawings. Furthermore, directional terms described by the present disclosure, such as up, down, top, bottom, front, back, left, right, inner, outer, side, surrounding, center, horizontal, vertical, longitudinal, axial, radial, uppermost or lowermost, etc., are only directions by referring to the accompanying drawings, and thus the used terms are used only for the purpose of describing embodiments of the present disclosure and are not intended to be limiting of the present disclosure.

In the drawings, units with similar structures are labeled with the same reference number.

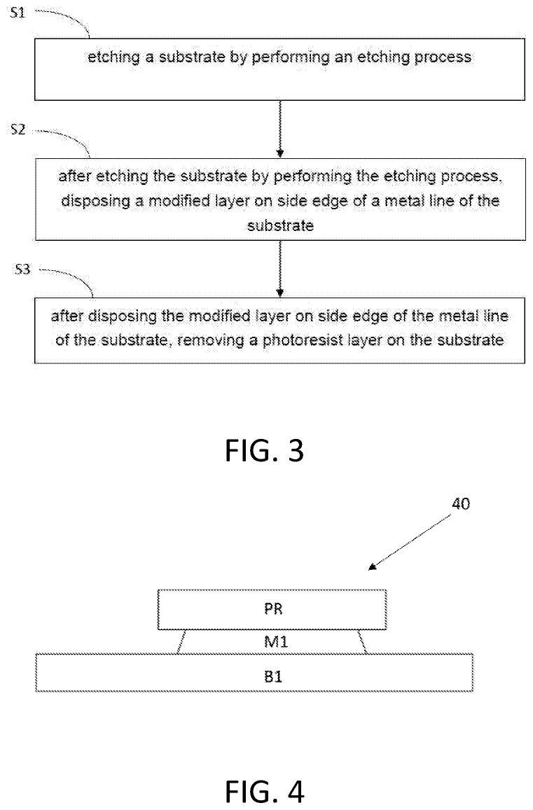

Please refer to FIG. 3, which shows a flowchart of a method of manufacturing a display panel according an embodiment of the present disclosure, wherein the method of manufacturing the display panel includes:

Step S1: etching a substrate by performing an etching process.

Step S2: after etching the substrate by performing the etching process, disposing a modified layer on a side edge of a metal line of the substrate.

Step S3: after disposing the modified layer on the side edge of the metal line of the substrate, removing a photoresist layer on the substrate.

In an embodiment of the present disclosure, a modified layer T1 is disposed on a metal line M1 by performing an oxidation process.

In an embodiment of the present disclosure, the modified layer T1 is disposed on the metal line M1 by performing a heat treatment process.

In an embodiment of the present disclosure, the modified layer T1 is disposed on the metal line M1 by performing an ion implantation process.

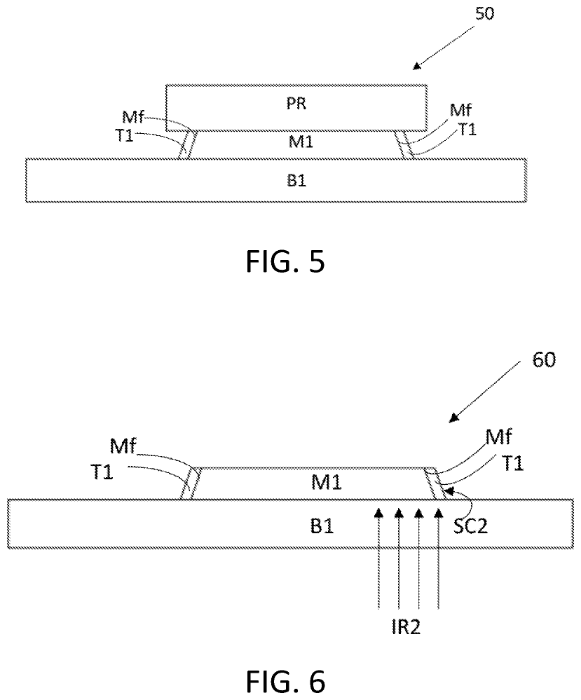

Please refer to FIG. 4, FIG. 5, and FIG. 6, which are respectively a schematic block diagram according to a first state of a display panel according an embodiment of the present disclosure, a schematic block diagram according to a second state of the display panel according an embodiment of the present disclosure, and a schematic block diagram according to a third state of the display panel according an embodiment of the present disclosure.

The present disclosure provides a method of manufacturing a display panel for improving light leakage of panel, as shown in FIG. 4 of a first state 40 of the display panel, wherein the metal line M1 is disposed above a substrate B1, and a photoresist layer PR is disposed above the metal line M1. In the first state of the display panel, the substrate B1 can be etched by performing an etching method. Please further refer to FIG. 5. FIG. 5 shows a second state 50 of the display panel, wherein a side edge Mf of the metal line M1 is further disposed a modified layer T1. Please refer to FIG. 6. FIG. 6 shows a third state 60 of the display panel, wherein a photoresist layer PR disposed above the metal line M1 is removed.

Please further refer to FIG. 6. In the third state 60 of the display panel, by additionally disposing the modified layer T1 to the side edge Mf of the metal line M1, when an incident light IR1 irradiated upward from below the substrate B1 produces a diffraction SC2 and illuminates the modified layer T1, a rough surface of the modified layer T1 forms a diffuse reflection of the incident light, reducing the specular reflection of the diffraction SC2. In other words, compared with the prior art, the display panel of the present disclosure further achieves the effect of reducing light leakage of the metal line M1 to improve the display contrast of the display panel.

In an embodiment of the present disclosure, the modified layer T1 covers the side edge Mf of the metal line M1.

In an embodiment of the present disclosure, an oxygen content of the modified layer T1 is greater than an oxygen content of the side edge Mf of the metal line M1.

In an embodiment of the present disclosure, a carbon content of the modified layer T1 is greater than a carbon content of the side edge Mf of the metal line M1.

In an embodiment of the present disclosure, an ion content of the modified layer T1 is greater than an ion content of side edge of the metal line M1.

In an embodiment of the present disclosure, material of the metal line M1 includes copper.

In an embodiment of the present disclosure, material of the modified layer T1 includes copper oxide.

In an embodiment of the present disclosure, the modified layer T1 is formed by applying an oxidative plasma treatment process to the metal line M1. For example, when the constituting material of the metal line M1 includes copper, the constituting material of the modified layer T1 includes copper oxide.

Due to the panel and the manufacturing method thereof of the present disclosure, the method of manufacturing the display panel is used for improving metal light leakage, including etching a substrate by an etching process. After etching the substrate by performing the etching process, a modified layer is disposed on a side edge of a metal line of the substrate, and after disposing the modified layer on the side edge of the metal line of the substrate, a photoresist layer on the substrate is removed. By disposing the modified layer to absorb reflection of diffracted light, light leakage at the side edge of the metal line is reduced, and display contrast is improved.

Although the present disclosure is described via one or more embodiments, those of ordinary skill in the art can come up with equivalent variations and modifications based upon the understanding of the specification and the accompanying drawings. The present disclosure includes all such modifications and variations, and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

The above are only preferred embodiments of the present disclosure, and it should be noted that those skilled in the art can also make several improvements and refinements without departing from the principles of the present disclosure. These improvements and refinements should also be considered in a protected range of the present disclosure.

What is claimed is:

1. A method of manufacturing a display panel, comprising:
etching a substrate by performing an etching process;
after etching the substrate by performing the etching process, disposing a modified layer on a side edge of a metal line of the substrate; and
after disposing the modified layer on the side edge of the metal line of the substrate, removing a photoresist layer on the substrate.

2. The method of manufacturing the display panel according to claim 1, wherein the modified layer is disposed on the metal line by performing an oxidation process.

3. The method of manufacturing the display panel according to claim 1, wherein the modified layer is disposed on the metal line by performing a heat treatment process.

4. The method of manufacturing the display panel according to claim 1, wherein the modified layer is disposed on the metal line by performing an ion implantation process.

5. The method of manufacturing the display panel according to claim 1, wherein material of the metal line comprises copper.

6. The method of manufacturing the display panel according to claim 1, wherein the modified layer is formed by applying an oxidative plasma treatment process to the metal line.

7. The method of manufacturing the display panel according to claim 1, wherein material of the modified layer comprises copper oxide.

8. The method of manufacturing the display panel according to claim 1, wherein the modified layer covers the side edge of the metal line.

9. A display panel, comprising:
a substrate; and
a metal line, disposed on the substrate;
wherein a side edge of the metal line is provided with a modified layer.

10. The display panel according to claim 9, wherein an oxygen content of the modified layer is greater than an oxygen content of the side edge of the metal line.

11. The display panel according to claim 9, wherein a carbon content of the modified layer is greater than a carbon content of the side edge of the metal line.

12. The display panel according to claim 9, wherein an ion content of the modified layer is greater than an ion content of the side edge of the metal line.

13. The display panel according to claim 9, wherein material of the metal line comprises copper.

14. The display panel according to claim 9, wherein material of the modified layer comprises copper oxide.

15. The display panel according to claim 9, wherein the modified layer covers the side edge of the metal line.

16. A display panel, comprising:
a substrate; and
a metal line, disposed on the substrate;
wherein a side edge of the metal line is provided with a modified layer, the modified layer covers the side edge of the metal line, and an oxygen content of the modified layer is greater than an oxygen content of the side edge of the metal line.

17. The display panel according to claim 16, wherein a carbon content of the modified layer is greater than a carbon content of the side edge of the metal line.

18. The display panel according to claim 16, wherein an ion content of the modified layer is greater than an ion content of the side edge of the metal line.

19. The display panel according to claim 16, wherein material of the metal line comprises copper.

20. The display panel according to claim 16, wherein material of the modified layer comprises copper oxide.
